(19) United States
(12) Patent Application Publication
(10) Pub. No.: US 2003/0068839 A1
(43) Pub. Date: Apr. 10, 2003

(54) Forming solder walls and interconnects on a substrate

(76) Inventors: Allen Chris Culuris, Santa Rosa, CA (US); James Philip Stephens, Sebastopol, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 09/972,695

(22) Filed: Oct. 4, 2001

(51) Int. Cl. H01L 21/44; H01L 21/48; H01L 21/50

(52) U.S. Cl. 438/106; 438/612; 438/116

(57) ABSTRACT

Formation of solder walls on a substrate. Solder walls and interconnects are formed on a substrate by placing solder preforms on the substrate, covering the substrate and preforms with a vented top plate which is not solder wettable and is held apart from the substrate by spacers, and reflowing the solder.

### FIELD OF THE INVENTION

The present invention relates to methods of forming solder walls and columnar solder interconnects on a substrate such as a printed circuit board, and is particularly applicable to forming such features on multi-chip modules.

### ART BACKGROUND

Printed circuit boards are ubiquitous in electronic devices, providing for increased component density. In very high density circuits, integrated circuits, semiconductor devices, and passive components in unpackaged form are mounted directly to a substrate. This is known as multi-chip-module or MCM manufacturing.

As physical device density increases along with operating frequencies, the designer is faced with the need to provide electrical and RF isolation between sections of circuitry mounted on the substrate. In many cases, such as where unpackaged semiconductor devices are mounted directly to the substrate, environmental enclosure must be provided as well.

A prior art solution to these problems divided up the MCM into smaller sections and mounted the substrate in a machined metal enclosure which provided environmental protection and RF isolation between sections of circuitry. This approach is very expensive.

Another technique is to form walls of solder which enclose the substrate and also extend between sections of circuitry on the substrate to provide isolation. Solder extrusions may also be used for interconnects when the substrate is mounted to a larger printed circuit board.

The method known to the art for forming these solder walls and interconnects is to design and produce a mask which is used to stencil containment material onto the substrate, masking off areas where solder is not desired. Once the stencil has been used to deposit containment material, typically a paste, solder paste is applied to the areas not covered by the containment mask. The solder is melted using known techniques, such as vapor reflow, forming the desired solder walls and possibly interconnects. The paste mask must then be removed and the substrate cleaned before placement of components onto the substrate can commence.

This paste containment mask (PCM) method is expensive and time consuming, requiring specific tools such as stencils to be produced, the substrate must be masked, solder paste applied, reflowed, and the paste mask removed. The height of the solder walls is difficult to control using this approach, as it is dependant on the ability to form the mask of suitable height and stability.

What is needed is a method of forming solder walls on a substrate which does not involve the use of such masks.

### SUMMARY OF THE INVENTION

Solder wall and interconnect columns are fabricated on a substrate using spacers and simplified flat plate tooling. Solder preforms are attached to the substrate using spacers and flat plate tooling. The flat plate tooling is selected to be non wettable by solder. The flat plate tooling traps the solder preforms and in conjunction with the spacers, provides walls and interconnects of the appropriate shape and thickness.

### BRIEF DESCRIPTION OF THE DRAWINGS

The present invention is described with respect to particular exemplary embodiments thereof and reference is made to the drawings in which:

FIG. 1 is a top view of a multi chip module (MCM) with solder walls and interconnects,

FIG. 2 is a cross section of tooling used to produce solder walls and interconnects.

### DETAILED DESCRIPTION

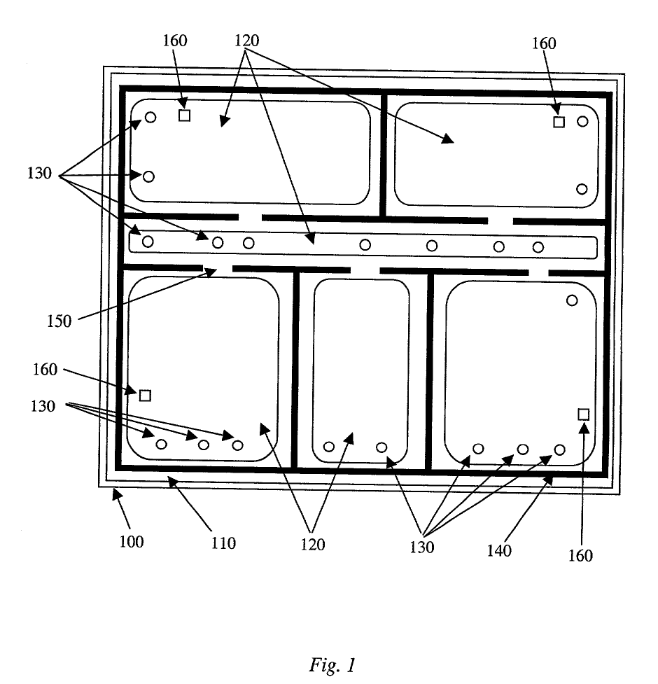

Referring to FIG. 1, substrate 100 consists of an insulating material with conductive material 110, usually copper film, applied to one or both sides. The insulating substrate may be fiberglass, PTFE or ceramic loaded laminates, ceramic, or sapphire depending on needed dielectric requirements. The copper conductors are typically covered with a solder mask where solder adhesion is not desired. Blank areas 120 are used to mount components. Pads 130 are used for interconnects between devices mounted in areas 120, and may be used for interconnects between substrate 100 and the larger device to which it is eventually mounted.

In common with prior art techniques, the exposed copper surface of the substrate is cleaned and coated with a suitable flux material, such as WMA-SMQ65 flux from Indium Corporation of America.

In departure from prior techniques, solder preforms 140 are used. A preform is a solder shape fabricated in the desired pattern, for example comprising containing walls and isolating fingers. Gaps 150 present in the preform allow for interconnects to other circuitry on substrate 100. Preforms may be fabricated using a number of techniques, such as CNC laser milling or molding. Preforms may be in multiple pieces, or one piece.

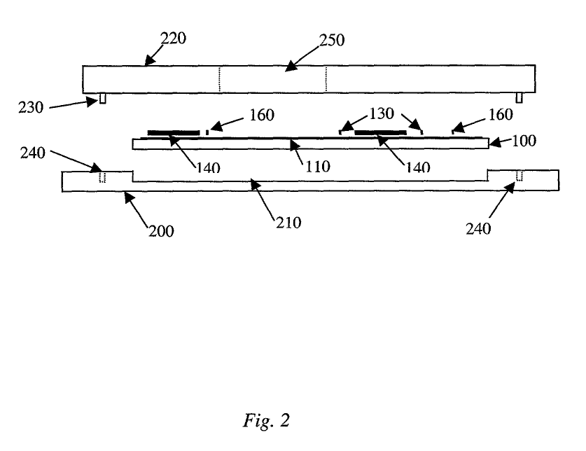

The substrate is mounted on a base plate. In one embodiment, 0.003 inch thick single-sided Kapton tape is used to secure the substrate to a base plate larger than the substrate, for example, formed from a 3×3×⅛ inch thick piece of aluminum. The use of Kapton tape on the sides of the substrate provides a barrier to prevent solder from wetting the side plating of the substrate. In the preferred embodiment as shown in FIG. 2, a larger process carrier 200 is used, the process carrier designed to precisely locate and receive a number of substrates and their flat plate tooling. In FIG. 2, substrate 100 fits into recess 210 of process carrier 200.

After placing the appropriate flux and solder paste as required, solder preform 140 and solder pucks 130 are placed on the substrate where walls 140 and interconnects 130 are to be formed. Spacers 160 are also placed on the substrate. In the preferred embodiment, the spacers are 0.020 inches in height, with the solder preforms and pucks being 0.025 inches in height prior to reflow. Spacers 160 may be ceramic, held in place with an adhesive such as epoxy. Spacers may also take the form of solid pucks of conductive material, such as copper, or tin plated brass.

Next top plate 220 is placed over the substrate, resting on the preforms. In the preferred embodiment, the plate is a material which is not wettable by solder, aluminum for example. The top plate is vented 250 to permit the outgassing of flux during the heating process. If vents are not provided, the outgassing flux will blow through one or more of the solder preform walls. The top plate may also contain spacers.

The top plate may be clamped in place, or held by its own weight. In the preferred embodiment, alignment pins 230 on the top plate mate with matching recesses 240 in the process carrier. The assembly comprising process carrier 200, one or more substrates 100 with preforms 140, interconnects 130, spacers 160, and top plates 220 is heated, causing the solder to reflow, wetting the substrate but not the top plate. The spacers control the height of the solder walls and interconnects. Heating must be carefully controlled and uniform.

The assembly is removed from the oven, top plates 220 removed, and the substrate washed to remove flux residue.

The foregoing detailed description of the present invention is provided for the purpose of illustration and is not intended to be exhaustive or to limit the invention to the precise embodiments disclosed. Accordingly the scope of the present invention is defined by the appended claims.

What is claimed is:

1. A method of forming features on conductive areas of a substrate comprising:
placing a preformed solder structure on a conductive portion of the substrate,
placing the non-wettable surface of a top plate on top of the solder structure,
heating the solder structure to reflow it to the substrate, and
maintaining a predetermined distance between the conductive surface of the substrate and the top plate using spacers.

2. The method of claim 1 where the feature is a solder wall.

3. The method of claim 2 where the solder wall separates areas of the substrate.

4. The method of claim 1 where the feature includes interconnects

5. The method of claim 1 where the top plate has a non-wettable surface.

6. The method of claim 1 where the top plate is non-wettable .

7. The method of claim 6 where the top plate is aluminum.

8. The method of claim 1 where the top plate is vented.

9. The method of claim 1 where the spacers are placed on the substrate.

10. The method of claim 9 where the spacers are nonconductive.

11 The method of claim 9 where the spacers are conductive.

12. The method of claim 11 where one or more of the spacers is used as an interconnect.

13. The method of claim 1 where the spacers are integral to the top plate.

14. A substrate having conductive areas on at least one side of the substrate, some of the conductive areas having solder features formed by the process of:
placing a preformed solder structure on a conductive portion of the substrate,
placing the non-wettable surface of a top plate on top of the solder structure,
heating the solder structure to reflow it to the substrate, and
maintaining a predetermined distance between the conductive surface of the substrate and the top plate using spacers.
